(19) United States
(12) Patent Application Publication
(10) Pub. No.: US 2014/0109953 A1
(43) Pub. Date: Apr. 24, 2014

(54) MOUNTING AND INSTALLING SYSTEM FOR SOLAR PHOTOVOLTAIC MODULES AND ARRAYS

(71) Applicant: KB RACKING INC., Toronto (CA)

(72) Inventor: PETER AULICH, Toronto (CA)

(73) Assignee: KB RACKING INC., TORONTO (CA)

(21) Appl. No.: 13/656,391

(22) Filed: Oct. 19, 2012

(51) Int. Cl. H01L 31/048

(52) U.S. Cl. 136/251

(57) ABSTRACT

A system for mounting and installing of solar photovoltaic modules is provided. The system is a lightweight, quick to install, and aerodynamic mounting system for integrating solar photovoltaic modules and solar photovoltaic arrays for low-slope rooftops. The mounting and installing of solar photovoltaic modules includes a rubber mat, a rail member positioned atop the rubber mat, a link member coupling multiple rails, a bottom link member and a top link member coupled to a rail member, a rear wind deflector coupled to a top link member, a flanking wind deflector coupled to a top link member and a rail member.

### BACKGROUND OF THE INVENTION

1. Field of the Invention

The present invention relates generally to a system for integrating and mounting solar photovoltaic modules and arrays, and more specifically, the present invention relates to a lightweight, quick to install and aerodynamic mounting system for integrating solar photovoltaic modules and solar photovoltaic arrays for low-slope rooftops.

2. Description of the Related Art

Solar irradiance is the most ample source of energy on this planet, which maintains the majority of all life on earth. Being able to harness the abundant solar energy and convert it into usable electricity is one of the main contributors behind the growth of the solar photovoltaic industry.

As the industry continues to grow and the technology advances, solar photovoltaic modules (“PV Modules”) become increasingly popular, and so do the means by which they are utilized. Countries all over the world encourage their populace to contribute and generate their own electricity by means of such PV modules and offer them a variety of incentives. Business owners with large low-slope rooftops are particularly attracted to this idea because it is a means by which income is created, savings are procured, and space that is otherwise unused and is in ample supply can be effectively utilized.

The PV modules are typically positioned on rooftops facing either north or south depending on the location of the rooftop with respect to the equator. This direction ensures maximum exposure of the PV modules to the sun throughout the year. Similarly, the tilt angle at which a PV module is inclined directly affects the overall performance thereof throughout each day. This tilt angle is directly proportional to the latitude at which the PV modules are mounted. The correct alignment of these PV modules to the right angle and direction is crucial to their effectiveness.

Therefore, solar photovoltaic mounting systems (“Mounting System”) are vital in the design aspects. It is imperative to develop a mounting system that can effectively aim each PV module at the optimal angle and direction. However, at the same time, it must be able to secure the PV modules to withstand all sorts of forces that may be experienced on an open rooftop; from wind loads and snow loads to seismic loads, among many others. Uplift forces and drag forces are the most crucial of these forces; they are highly dependent on the wind zone of the building and the height. An ideal racking system must be both lightweight and aerodynamic because many rooftops are not designed to carry additional dead loads. If a mounting system is very lightweight, it must be equally as aerodynamic in order to eliminate any compensating ballast.

When PV modules are grouped together, they are referred to as solar photovoltaic arrays (hereinafter referred to as “PV Arrays”). PV arrays are crucial in the solar industry for creating efficient and effective systems. When PV modules are grouped together, they can form an interconnected grid wherein each PV module is connected to its adjacent. PV module and so on, in both directions. This arrangement is crucial because a strong interconnection can allow for system weight and features of components further away to share loading and share aerodynamic qualities. When implemented correctly, this can lead to some PV arrays with little to no extra ballasting at all, and ideally, a system that is entirely self-ballasted. The larger the PV arrays, the larger their averaging areas, and therefore the stiffer the system, the more aerodynamic it becomes, and the more self-dependent it becomes with respects to additional ballast. Determining their averaging area, whether the system is a two-by-two (whereas this would be described as two PV modules north-south and two PV modules east-west), or whether the system is three-by-three, or four-by-four, and so on, is the key to making a PV array self-ballasted.

In light of the foregoing, there exists a need to provide a mounting and installation system for PV modules and PV arrays that is lightweight quick to install, and aerodynamic in nature, in addition, the mounting and installation system should be self-ballasted and should eliminate the above mentioned limitations of the prior art systems.

### SUMMARY

An object of the present invention is to provide a system for mounting and installing solar photovoltaic modules and solar photovoltaic arrays for low-slope rooftops that is lightweight, quick to install, and aerodynamic. The solar photovoltaic system includes a rail structure which provides a rigid linking platform to interconnect solar photovoltaic modules. The photovoltaic modules are secured atop a bottom and top link member by means of a module mounting clamp, which can additionally ground the solar photovoltaic modules. Forces acting on the solar photovoltaic system can be reduced by means of utilizing a rear and a flanking wind deflector. Linking wind deflector members are secured by means of self-drilling machine thread screws to additionally provide a bonding connection. Interconnecting the present invention into a solar photovoltaic array enables structural strengths and ballasting to be used supportively throughout the army where it may be required.

Another object of the present invention is to provide a method for mounting and installing of solar photovoltaic modules and arrays that provides an interconnected structural grid throughout the entire solar photovoltaic array using a series of linking members. The structure of the grid is distinguished by a combination of two groupings of members running in perpendicular axis to one another. One grouping of the current embodiment is a series of rail and connector members secured to one another along an axis, traditionally, although not limited to, North-South, with a similar innumerable series of this grouping running in parallel to this axis. The second grouping of the current embodiment is a series of solar photovoltaic modules and module mounting clamps secured to one another along a second axis perpendicular to the first grouping. This interconnected structural grid of groupings form a solar photovoltaic array capable of sharing ballasting effects and structural rigidity.

Another object of the present invention is to provide a method for mounting, and installing, of solar photovoltaic modules and arrays that provides reduced additional load requirements to an existing roof by means of a self-ballasting. One embodiment of the current invention is a lightweight aluminum alloy, which serves to little any additional loading on the roof than necessary. The method by which this self-ballasting technique is utilized is by means of the interconnectedness of the members throughout the solar photovoltaic array; this can allow the weight of the solar photovoltaic system to ballast itself under the proper circumstances. A self-ballasted solar photovoltaic array will not require ballasting stones anywhere throughout the array, enabling for lightweight system on rooftops that have a low load reserves.

Another object of the present invention is to provide a method for mounting and installing of solar photovoltaic modules and arrays that provides averaging areas to determine the ballasting scenario and stiffness of a solar photovoltaic array. These averaging areas may be affected by, but are not limited to, the wind exposure and the position within the interconnected grid. One embodiment of this method includes; dividing the solar photovoltaic array into sections deduced from their wind exposure; similarly dividing the sections into zones deduced from the solar photovoltaic module's position within the interconnected grid; allocating respective ballasting values according to their sections and zones.

Another object of the present invention is to provide a method for mounting and installing, of solar photovoltaic modules and arrays that provides an easy installation by using, a.

“click-in” installation mechanism. One embodiment of this method includes; a rail member and a bottom link member. Another embodiment of this method includes; a rail member and a top link member. In one aspect, a method is disclosed for installing of the click-in technique, the method includes the steps of; obtaining a rail member and a bottom link member; orienting and positioning the rail member atop the desired snake; setting the link member atop the rail member; pressing the link member with adequate downward force into the rail member. In one aspect of the current invention, click-in method ensues subsequent to a series of audible ‘clicking’ sounds coming from the locking of the bottom link member to the rail member.

Another object of the present invention is to provide a system for mounting and installing, of solar photovoltaic modules and arrays that provides a single electrical grounding connection throughout the entire solar photovoltaic array. By means of, but not limited to, bonding a combination of module mounting clamps, self-drilling machine thread screws, the “click-in” mechanism, and the interconnected structural grid of the solar photovoltaic array, the solar photovoltaic system can experience a single grounding/bonding connection.

In another embodiment of the present invention, a solar photovoltaic module integration system includes a roof protection mat, a rail member positioned atop the roof protection mat, a connector member that couples multiple rail members, a bottom link member and a top link member coupled to a rail member, a rear wind deflector coupled to a top link member and a rail member, and a flanking wind deflector coupled to a top link member and a rail member.

Embodiments of the present invention provide a photovoltaic array. The photovoltaic array includes a roof protection mat and a plurality of rail members that are substantially parallel and are disposed at a first predetermined distance from each other atop the roof protection mat. The photovoltaic array further includes a plurality of bottom link members, a plurality of top link members, and a plurality of link members. First bottom and top link members are removably secured atop a first rail member at a second predetermined distance from each other by way of first and second link members respectively, and second bottom and top link members are removably secured atop a second rail member at the second predetermined distance from each other by way of third and fourth link members respectively. A first photovoltaic module of a plurality of photovoltaic modules is removably secured to the first rail member by way of the first bottom and top link members, and to the second rail member by way of the second bottom and top link members. The first photovoltaic module forms a predetermined angle with respect to the first and second rail members, which is between 5 and 25 degrees. A plurality of wind deflectors and flanking wind deflectors is also provided, a wind deflectors conceals a rear portion of the first photovoltaic module and first and second flanking wind deflectors conceal first and second side portions of the first photovoltaic module, respectively.

There has thus been outlined, rather broadly, some of the features of the invention in order that the detailed description thereof may be better understood, and in order that the present contribution to the art may be better appreciated. There are additional features of the invention that will be described hereinafter.

In this respect, before explaining at least one embodiment of the invention in detail, it is to be understood that the invention is not limited in its application to the details of construction or to the arrangements of the components set forth in the following description or illustrated in the drawings. The invention is capable of other embodiments and of being used and carried out in various ways. Also, it is to be understood that the phraseology and terminology employed herein are for the purpose of the description and should not be construed as limiting.

Other objects and advantages of the present invention will become obvious to the reader and it is intended that these objects and advantages are within the scope and spirit of the present invention. To the accomplishment of the above and related objects, this invention may be embodied in the form illustrated in the accompanying drawings, attention being called to the fact, however, that the drawings are illustrative only, and that changes may be made in the specific construction illustrated and described within the scope of this application.

### BRIEF DESCRIPTION OF THE DRAWINGS

Various other objects, features and attendant advantages of the present invention will become fully appreciated as the same becomes better understood when considered in conjunction with the accompanying drawings, in which reference characters designate the same or similar parts throughout the several views, and wherein:

FIG. 1A is an upper perspective view of a solar photovoltaic array, in accordance with various embodiments of the present invention;

FIG. 1B is a side view of the solar photovoltaic array of FIG. 1A, in accordance with various embodiment of the present invention;

FIG. 1C is a top view of the solar photovoltaic array of FIG. 1A, in accordance with various embodiment of the present invention;

FIG. 2A is a front view of a rail member, in accordance with an embodiment of the present invention;

FIG. 2B is a top view of the rail member of FIG. 2A, in accordance with an embodiment of the present invention;

FIG. 2C is a side view of the rail member of FIGS. 2A and 2B, in accordance with an embodiment of the present invention;

FIG. 2D is an upper perspective view of the rail member of FIGS. 2A-C, in accordance with an embodiment of the present invention;

FIG. 3 is an upper perspective view of a bottom link member, in accordance with an embodiment of the present invention;

FIG. 4 is an upper perspective view of a top link member, in accordance embodiment of the present invention;

FIG. 5 is an upper perspective view of a connecting member, in accordance with an embodiment of the present invention;

FIG. 6A is an upper perspective view of a rear wind deflector, in accordance with an embodiment of the present invention;

FIG. 6B is a side view of the rear wind deflector of FIG. 6A, in accordance with an embodiment of the present invention;

FIG. 7A is an upper perspective view of a flanking wind deflector, in accordance with an embodiment of the present invention; and

FIG. 7B is an upper perspective view of a flanking wind deflector assembly, in accordance with an embodiment of the present invention.

As used in the specification and claims, the singular forms “a”, “an” and “the” include plural references unless the context clearly dictates otherwise. For example, the term “an article” may include a plurality of articles unless the context clearly dictates otherwise.

Those with ordinary skill in the art will appreciate that the elements in the Figures are illustrated for simplicity and clarity and are not necessarily drawn to scale. For example, the dimensions of some of the elements in the Figures may be exaggerated, relative to other elements, in order to improve the understanding of the present invention.

There may be additional components described in the foregoing application that are not depicted on one of the described drawings. In the event such a component is described, but not depicted in a drawing, the absence of such a drawing should not be considered as an omission of such design from the specification.

### DETAILED DESCRIPTION OF THE INVENTION

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting but rather to provide an understandable description of the invention.

Turning now descriptively to the drawings, in which similar reference characters denote similar elements throughout the several views, the figures illustrate a system for mounting and installing of solar photovoltaic modules and arrays, in accordance with various embodiments of the present invention. The system for mounting and installing of solar photovoltaic modules and arrays includes a roof protection mat, a rail member positioned atop the roof protection map, a link member that couples multiple rails, a bottom link member and a top link member coupled to a rail member, a rear wind deflector coupled to a top link member and a rail member, a flanking, wind deflector coupled to a top link member and a rail member.

### Solar Photovoltaic Array 100

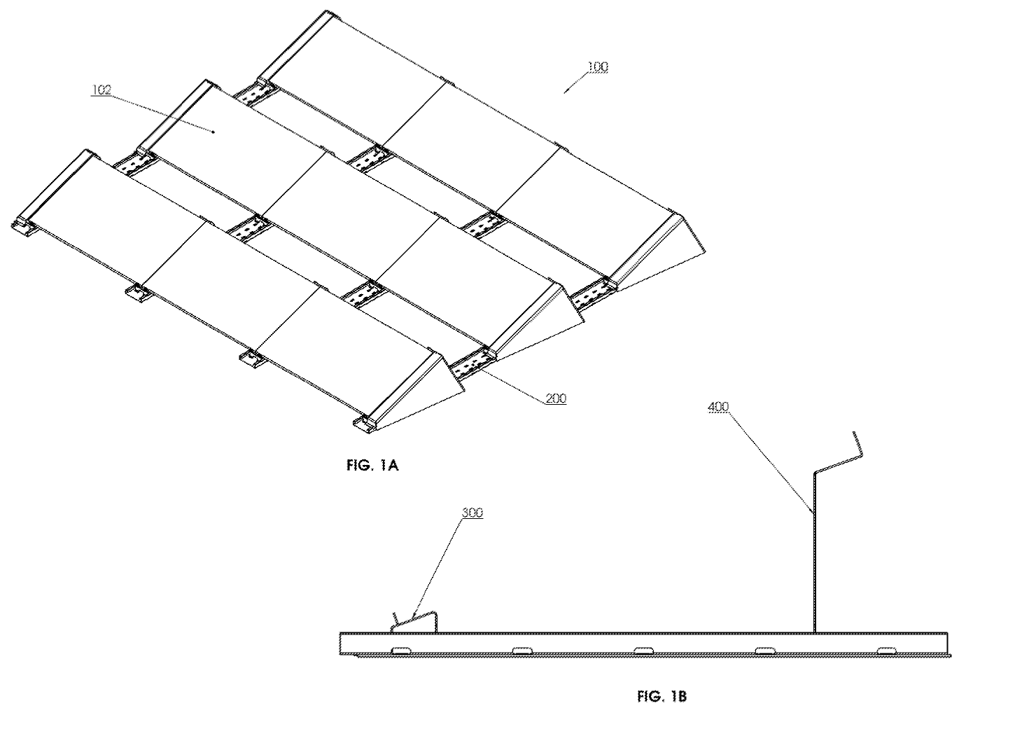

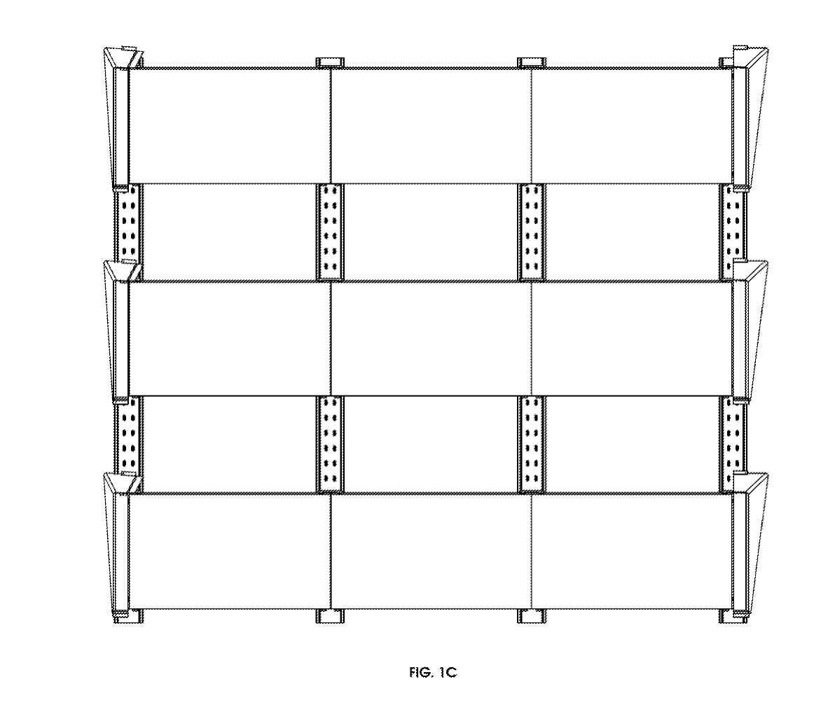

FIGS. 1A and 1B illustrate an example of a section of a solar photovoltaic (PV) module array 100, in accordance with various embodiments of the present invention. The solar PV module array 100 includes a plurality of solar PV modifies 102 that are tilted at an angle to most effectively capture solar radiation. For example, the solar PV modules 402 may be titled at an angle of 20 degrees with respect to the horizontal. It should be noted that the angles shown in FIGS. 1A and 1B are illustrative only, and they do not restrict the scope of the invention in any way. The solar PV modules 102 may therefore be mounted at angles other than those illustrated herein, such as, for example at any angle between 5 degrees and 25 degrees. The solar PV modules 102 are uniformly supported and secured at the angle by a bottom link member 300 and a top link member 400. Each solar photovoltaic module 102 requires two bottom link members 300 and two top link members 400 disposed at the corners thereof, and each bottom or top link member can support and secure up to two solar photovoltaic modules 102. These bottom and top link members 300 and 400 are then secured to an underlying plurality of rail member 200 to form columns of link members in the solar photovoltaic array 100. Parallel columns of rail members 200 and link members 300 and 400 form the foundation and structure of the solar photovoltaic array 100. FIG. 1C illustrates a top view of an example of a section of a solar photovoltaic module array 100. The details of the rail members 200 are illustrated in the forthcoming description.

### Rail Members 200

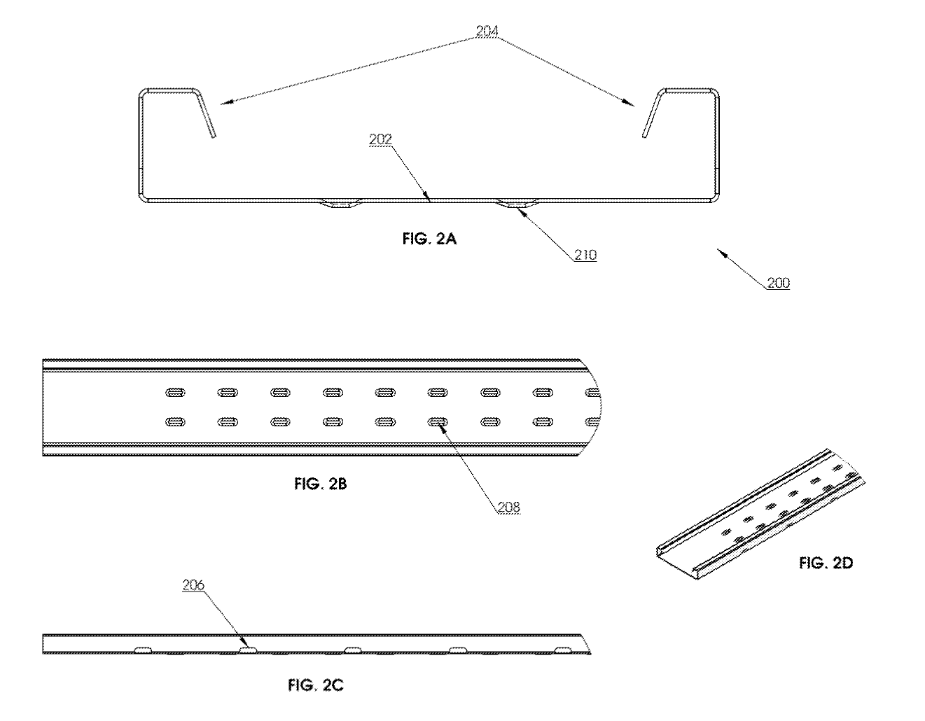

FIGS. 2A and 2B are front and top views of the rail member 200, in accordance with an embodiment of the present invention. FIG. 2C is a side view of the rail member of FIGS. 2A and 2B, in accordance with an embodiment of the present invention, and FIG. 2D is an upper perspective view of the rail member of FIGS. 2A-C, in accordance with an embodiment of the present invention. Preferably, the rail member 200 is roll-formed from 1.0 to 3.0 millimeter thick aluminum coils. The lengths of these rail members can vary, but are preferably 1.7, 3.5 and 5.2 meters in length to optimally accommodate a series of solar photovoltaic modules 102 in each column and to be able to customize the solar photovoltaic array layouts depending on their size and capacity. Referring, now to FIG. 2A, the rail member 200 generally forms a tray shaped channel 202 with the edges 204 folded back therefrom. The width of the rail member 200 allows for ballast of various sizes to either be mounted atop the rail securely, or fit protected within the channel. This channel additionally provides structural rigidity throughout the solar photovoltaic array 102. The rolled edges 204 are rolled to a desired height to allow for a click-in feature to be used with the link members 300 and 400 of FIGS. 1A and 1B. Prior to the roll-forming process, the rail member 200 is punched to create a linear elongated hole pattern 206 along the skirts functioning as a natural draining system throughout the causeway of the rail member 200. The rail member 200 is successively punched again to generate another unique hole pattern, creating circular shaped dimples 208 along the under carriage 210 which assist to increase the friction coefficient between the rail member 200 and a roof protection mat not shown in FIGS. 2A-2D) of the solar photovoltaic module to reduce the probability of the system being influence by horizontal wind forces. To install, the rail member 200 is generally, although not limited to, be positioned atop a protective mat, a sacrificial EDPM or TPO roofing material. In a situation involving an above-average possibility of seismic activity, a bonding solution is provided to fasten the rail member 200 to the rooftop in order to keep the system 100 stabilized and secure.

### Bottom Link Member 300

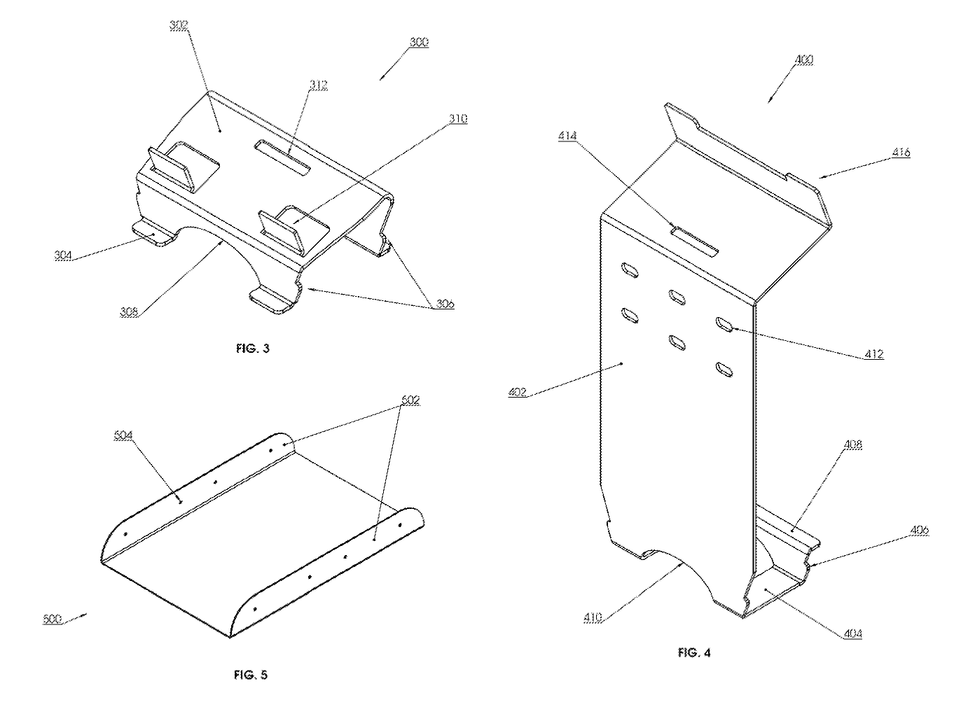

FIG. 3 is an upper perspective view of a bottom link member 300, in accordance with an embodiment of the present invention. The bottom link member 300 is composed of an aluminum body 302 which is generally formed and bent from sheet metal to the desired shape. This shape provides ideal distribution of loads through the body 302 and the feet 304 of the bottom link member 300 from the wind forces acting of the solar photovoltaic module 102. The tilt angle of the bottom link member can be manufactured to, but is not limited to, angles ranging from 5 to 25 degrees to accommodate the desired incident angles to utilize the solar radiation. The bottom link member 300 is symmetrical on either side to best hold and support two solar photovoltaic modules 102. Each side includes a notch 306, which acts as a click-in feature when used in conjunction with the rail member 200. This click-in feature not only acts to secure each bottom link member 300 to the rail member 200 tightly, but also ensures an electrical bonding connection between the bottom link member 300 and the rail member 200. Additionally, the bottom link member contains a cut-out 308 at the base to enable a means of management of electrical wires throughout the solar photovoltaic array 100. In some cases, a rubber trimming may be used on the cut-out 308 to protect and safely house the electrical wires. To facilitate the installation of the solar photovoltaic modules 102, the top of the bottom member 300 has two flanged surfaces 310 to align and guide the solar photovoltaic module 102 into place. In order to secure the module in place, the member comprises of a cut-out 312 which is used by a clamping device (not shown) to attach and additionally ground the solar photovoltaic module to the member,

### Top Link Member 400

FIG. 4 is an upper perspective view of a top link member 400, in accordance with an embodiment of the present invention. The top link member 400 is similar in construction to the bottom link member 300 of FIG. 3. The top link member 400 is also composed of an aluminum body and is generally manufactured from sheet metal. The top link member 400 is shaped similarly provides ideal distribution of loading through the body 402 and into feet 404 at the bottom of the top link member 400 due to its carefully crafted center of gravity. Additionally, each side includes click-in tabs 406, in the same manner as the bottom link member 300, which when used in conjunction with the rail member 200, form a secure mechanical and electrical bonding connection. The foot of the top link member 400 also provides notch 408 to allow for ease of installation using the click-in feature. To similarly assist in cable management of the solar modules array, the member features a cut out 410 at its foot to provide a safe and simple causeway for the electrical wires, in various embodiments of the present invention, a rubber trimming may also be used on the cut-out 410 to protect and safely house the electrical wires. The center most section accommodates a pattern of holes 412 that are used for mounting micro inverters, which can be mounted to the top link member 400 of each solar photovoltaic module as opposed to the roof, off the building or inside the building. These micro inverters can be fastened using any sequence of these holes 412 illustrated in FIG. 4. Electrical wire management, which uses wires to connect the modules and other electrical components of the solar photovoltaic array 102 together, may also be possible by use of clips, or other fastening devices, using these holes 412. To secure the module in place, the member comprises of a cut-out 414 which is used by a clamping device (not shown) to attach and additionally ground the solar photovoltaic module to the member, similarly as the bottom link member 300. The top section of the member features two tabs 416 which are used at a further step in the installation to mount and position rear wind deflectors or flanking wind deflectors.

### Connecting Member 500

FIG. 5 is an upper perspective view of a connecting member 500, in accordance with an embodiment of the present invention. This connecting member 500 is used to connect two adjacent rail members 200 in columns of a solar photovoltaic array 100. The connecting member 500 is composed of an aluminum body and is generally formed from sheet metal. Each side consists of tabs 502 generally naming 90 degrees to cradle two rail members. The rail members are secured together using fasteners through a series of holes 504 on both sides of the connecting member 500. Used correctly, this connecting member 500 may act as an electrical bonding path for interconnecting the solar photovoltaic array 100.

### Rear Wind Deflector 600

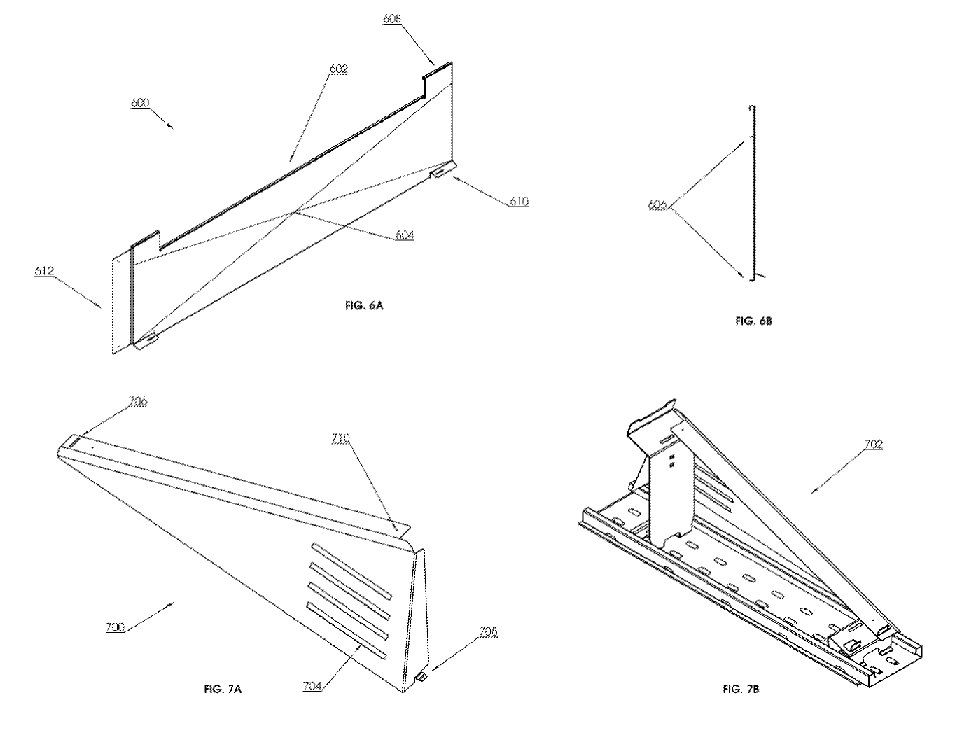

FIG. 6A is an upper perspective view of a rear wind deflector 600, and FIG. 6B is a side view of the rear wind deflector of FIG. 6A, in accordance with various embodiments of the present invention. The rear wind deflector 600 is generally used to conceal the rear portion of each solar photovoltaic module 102, to reduce uplift and drag forces that may be acting on the solar photovoltaic array 100 from turbulent winds. The rear wind deflector 600 is formed from aluminum sheet metal, and is ideally manufactured using brake form and bending processes. The rear wind deflector 600 forms a unique shape in order to increase its aerodynamics without compromising its effectiveness at reducing uplift and drag forces on the solar photovoltaic module 102. In the embodiment of the present invention, a large cut out 602 is introduced at the top to allow breathability and ventilation of the solar photovoltaic module 102, while still significantly decreasing the wind forces. To increase the stiffness, two diagonal brake form lines 604 are formed into the structure of the member; in addition, two flanges are introduced at the top and bottom 606 to provide additional stiffness. For installation purposes, the design features two bends with a cut-out slit 608 at the top of the member for ease of mounting and securing onto the top link member 400. Similarly, two tabs elongate horizontally 610 from the bottom to sit atop the rail member 200, to be further fastened and secured to the rail member 200. These two bends with cut-out notches 610 provide extra flexibility in the system 100 during installation to account for different module sizes and customizability of the solar photovoltaic array. Furthermore, the rear wind deflector 600 assists in interconnecting the solar photovoltaic array 100 with a large interlocking flange 612 that is used to join adjacent rear wind deflectors 600. This acts to further increase the stiffness of the entire solar photovoltaic array 100.

### Flanking Wind Deflector 700

FIG. 7A is an upper perspective view of a flanking wind deflector 700, and FIG. 7B is an upper perspective view of a flanking, wind deflector assembly 702, in accordance with various embodiments of the present invention. The flanking wind deflector 700 is generally used to conceal the sides of the solar photovoltaic array 100 to reduce the effects of uplift and drag wind forces on a given rooftop. The flanking wind deflector 700 is similarly formed of sheet metal aluminum. The flanking wind deflectors 700 form an ideal angle (as shown in FIG. 7A) of declination ranging for 0 to 20 degrees depending on the solar photovoltaic tilt of the PV module 102. To assist in reducing uplift and drag forces on the system 100, and to increase natural cooling and ventilation of the solar photovoltaic modules 100, the side of the flanking wind deflector has several ventilation slits 704. These slits can be but are not limited to this pattern. For installation purposes, the design features a slit 706 at the top of the member for ease of mounting and securing onto the bottom link member 300, as demonstrated in FIG. 7B. This feature additionally forces the flanking wind deflector 700 to be properly aligned to the top link member 400. At the rear of the flanking wind deflector 700 is a tab which elongate horizontally from the bottom 708 to sit atop the rail member 200, to be further fastened and secured to the rail member 200, also demonstrated in FIG. 7B. Along with these features, 2 holes on the top of the design 710 allow the flanking rear deflector 700 to be secured to the underlying, structure, as shown in FIG. 7B. In the same manner to the rear wind deflector 600 described in the previous description, the flanking wind deflector 700 assists in interconnecting the solar photovoltaic array 100 with a large interlocking flange (not shown) that is used to join adjacent rear wind deflectors 600. This acts to further increase the stiffness of the entire solar photovoltaic array 100.

Thus, the present invention has been described herein with reference to a particular embodiment for a particular application. Although selected embodiments have been illustrated and described in detail, it may be understood that various substitutions and alterations are possible. Those haying ordinary skill in the art and access to the present teachings may recognize additional various substitutions and alterations are also possible without departing from the spirit and scope of the present invention.

What is claimed is:

1. A photovoltaic array comprising:
a plurality of rail members, wherein the plurality of rail members are substantially parallel and are disposed at a first predetermined distance from each other;
a plurality of bottom link members;
a plurality of top link members,
wherein first bottom and top link members are removably secured atop a first rail member of the plurality of rail members at a second predetermined distance from each other, and second bottom and top link, member are removably secured atop a second rail member of the plurality of rail members at the second predetermined distance from each other; and
a plurality of photovoltaic modules,
wherein a first photovoltaic module of the plurality of photovoltaic modules is removably secured to the first rail member by way of the first bottom and top link members, and to the second rail member by way of the second bottom and top link members, such that the first photovoltaic module forms a predetermined angle with respect to the first and second rail members.

2. The photovoltaic array of claim 1, wherein the plurality of bottom and top link members are removably secured to the plurality of rail members such that the plurality of bottom and the top link members form a grid structure thereover.

3. The photovoltaic array of claim 2, wherein the plurality of photovoltaic panels are disposed on the grid structure.

4. The photovoltaic array of claim 2, wherein each of the plurality of photovoltaic panels is self-ballasted.

5. The photovoltaic array of claim 1, wherein the plurality of rail members, the plurality of bottom link members, and the plurality of top link members are made up of an aluminum alloy.

6. The photovoltaic array of claim 1 further comprising a single electrical bonding connection for electrically connecting the plurality of photovoltaic modules.

7. The photovoltaic array of claim 1, wherein the first predetermined angle is between about 5 degrees and about 25 degrees.

8. The photovoltaic array of claim 1, wherein each of the plurality of rail members is roll-formed from 1.0 to 3.0 millimeter thick aluminum coils.

9. The photovoltaic array of claim 1, wherein each of the plurality of rail members comprises a tray shaped channel.

10. The photovoltaic array of claim 1, wherein each of the plurality of rail members comprises a plurality of holes along a length thereof for natural draining.

11. The photovoltaic array of claim 1, wherein each of the plurality of rail members comprises a plurality of circular dimples along an under carriage thereof for increasing friction coefficient between the rail member and a roof protection mat.

12. The photovoltaic array of claim 1, wherein each of the plurality of bottom and top link members comprises a notch for enabling a click-in fitting with the corresponding rail member.

13. The photovoltaic array of claim 1, wherein each of the plurality of bottom and top link members comprises two flanged surfaces for aligning and guiding a corresponding photovoltaic module on the bottom and top link members.

14. The photovoltaic array of claim 1 further comprising a plurality of connecting members, wherein each of the plurality of connecting members secures the corresponding bottom or top link member to the corresponding rail member.

15. The photovoltaic array of claim 1 further comprising a plurality of wind deflectors, wherein each of the plurality of wind deflectors conceals a rear portion of a corresponding photovoltaic module to reduce uplift and drag forces acting thereover.

16. The photovoltaic array of claim 1 further comprising a plurality of flanking wind deflectors, wherein each of the plurality of flanking wind deflectors conceals a side portion of a corresponding photovoltaic module to reduce uplift and drag forces acting thereover.

17. A photovoltaic array, the photovoltaic array comprising:
a roof protection mat;
a plurality of rail members, wherein the plurality of rail members are substantially parallel and are disposed at a first predetermined distance from each other atop the roof protection mat;
a plurality of bottom link members;
a plurality of top link members,
a plurality of link members;
wherein first bottom and top link members are removably secured atop a first rail member at a second predetermined distance from each other by way of first and second link members respectively, and second bottom and top link members are removably secured atop a second rail member at the second predetermined distance from each other by way of third and fourth link members respectively;
a plurality of photovoltaic modules,
wherein a first photovoltaic module of the plurality of photovoltaic modules is removably secured to the first rail member by way of the first bottom and top link members, and to the second rail member by way of the second bottom and top link members, such that the first photovoltaic module forms a predetermined angle with respect to the first and second rail members;
a plurality of wind deflectors, wherein a first wind deflectors conceals a rear portion of the first photovoltaic module; and
a plurality of flanking wind deflectors, wherein first and second flanking wind deflectors conceal first and second side portions of the first photovoltaic module, respectively.

18. The photovoltaic array of claim 17, wherein the plurality of bottom and top link members are removably secured to the plurality of rail members such that the plurality of bottom and top link members forms a grid structure thereover.

19. The photovoltaic array of claim 17, wherein each of the plurality of photovoltaic panels is self-ballasted.

20. The photovoltaic array of claim 1, wherein the plurality of rail members, the plurality of bottom link members, the plurality of top link members, the plurality of link members, the plurality of wind deflectors and the plurality of flanking wind deflectors are made of an aluminum alloy.
